(19) United States
(12) Patent Application Publication
(10) Pub. No.: US 2025/0327742 A1
(43) Pub. Date: Oct. 23, 2025

(54) Method and Device for Fitting Spectrum in Off-Axis Integrated Cavity Disturbed by Radio Frequency Noise

(71) Applicant: China Jiliang University, Hangzhou City, (CN)

(72) Inventors: Kunyang Wang, Hangzhou City (CN); Shiqing Xu, Hangzhou City (CN); Ruonan Zhang, Hangzhou City (CN); Tianzhi Jiang, Hangzhou City (CN); Ying Tian, Hangzhou City (CN); Jingtao Zhao, Hangzhou City (CN)

(21) Appl. No.: 18/735,426

(22) Filed: Jun. 6, 2024

(30) Foreign Application Priority Data
Apr. 22, 2024 (CN) 202410483468.4

(51) Int. Cl. G01N 21/31; G01N 21/39; G01R 29/26

(52) U.S. Cl. CPC G01N 21/31; G01N 21/39; G01R 29/26; G01N 2021/3196

(57) ABSTRACT

This application relates to a method and a device for fitting a spectrum in an off-axis integrated cavity disturbed by radio frequency noise. The method includes: setting a single mode output light field of a laser; obtaining a maximum cutoff frequency and a power spectral density of radio frequency white noise generated by a radio frequency noise source, and converting a disturbance of the radio frequency white noise in electricity to a phase disturbance of the light field to obtain a converted power spectral density; determining a laser power spectrum according to the set light field, and the maximum cutoff frequency and the converted power spectral density of the radio frequency white noise; obtaining a length and a cavity mirror reflectivity of an off-axis integrated cavity system, and an initial light intensity and a real-time light intensity when the off-axis integrated cavity system runs; and constructing a forward fitting model.

### CROSS REFERENCE TO RELATED APPLICATION

This application claims the benefit of and takes priority from Chinese Patent Application No. 202410483468.4 filed on Apr. 22, 2024, the contents of which are herein incorporated by reference.

### TECHNICAL FIELD

This application relates to the technical field of spectral measurement, and in particular, to a method and a device for fitting a spectrum in an off-axis integrated cavity disturbed by radio frequency noise.

### BACKGROUND

Off-axis integrated cavity output spectroscopy is a high-sensitivity gas detection technology suitable for atmospheric trace gas detection, has the advantages of simple structure, stable system, high integration degree, and the like since a light beam and an optical axis in an integrated cavity do not need to be strictly coaxial, and has become a hot research focus in the field of atmospheric trace gas detection in recent years. However, a phenomenon of random fluctuations in a laser phase will occur when laser emits into an optical resonant cavity off axis, so as to generate optical cavity mode noise. Even in a case of fully off-axis, there is still some residual cavity mode noise that cannot be suppressed. Therefore, mode noise becomes a main reason that affects measurement accuracy of an Off-Axis Integrated Cavity Output Spectroscopy (OA-ICOS) system.

To solve this problem, researchers have carried out some work to suppress cavity mode noise. Part researchers have injected radio frequency white noise (1 to 1500 MHz) after being subjected to 30 MHz low-pass filtering into a laser current to broaden a laser linewidth to reduce the cavity mode noise, and have achieved a Minimum Detectable Absorption Rate (MDA) of 4.3×10⁻⁵ Hz-½ within an average time of 1000 ms. In addition, other researchers have injected radio frequency white noise (50 to 1500 MHz) into a quantum cascade laser. Compared with not injecting the radio frequency white noise, the performance of the OA-ICOS system has been improved by nearly ten times. However, a problem that the radio frequency white noise disturbs a broadened linewidth of an absorption spectral line in researches described above cannot be solved, and a suppression principle of a radio frequency white noise disturbance is not further explained, so that a commonly used linear function cannot fit a broadened spectral line to cause a fitting error and affect the measurement accuracy.

### SUMMARY

To solve the problems that a broadened spectral line cannot be fitted when cavity mode noise is suppressed to cause a fitting error and affect measurement accuracy in a related technology at least to a certain extent, this application provides a method and a device for fitting a spectrum in an off-axis integrated cavity disturbed by radio frequency noise.

A solution of this application is as follows:

According to a first aspect of embodiments of this application, a method for fitting a spectrum in an off-axis integrated cavity disturbed by radio frequency noise is provided, including:
setting a single mode output light field of a laser;
obtaining a maximum cutoff frequency and a power spectral density of radio frequency white noise generated by a radio frequency noise source, and converting a disturbance of the radio frequency white noise in electricity to a phase disturbance of the light field to obtain a converted power spectral density;
determining a laser power spectrum according to the set light field, and the maximum cutoff frequency and the converted power spectral density of the radio frequency white noise;
obtaining a length and a cavity mirror reflectivity of an off-axis integrated cavity system, and an initial light intensity and a real-time light intensity when the off-axis integrated cavity system runs; and
constructing a forward fitting model containing a spectral absorption coefficient of the radio frequency white noise when the cavity mirror reflectivity of the off-axis integrated cavity system approaches 1. The forward fitting model is represented as a functional relationship between the spectral absorption coefficient inside the cavity and the laser power spectrum, the length of the off-axis integrated cavity system, and the initial light intensity and the real-time light intensity when the off-axis integrated cavity system runs.

Preferably, the method further includes:
obtaining the spectral absorption coefficient inside the cavity when the off-axis integrated cavity spectrum runs according to the forward fitting model, and generating a fitting result;
performing fitting verification on the fitting result according to fitting verification data; and
when the fitting verification fails, modifying the forward fitting model until the fitting verification is succeeded.

Preferably, the method further includes:
generating a prediction result according to the forward fitting model when the fitting verification is succeeded; and
performing prediction verification on the prediction result according to prediction verification data; and
when the prediction verification fails, modifying the forward fitting model until the prediction verification is succeeded.

Preferably, the method further includes:
applying the forward fitting model to fitting the spectrum in the off-axis integrated cavity disturbed by the radio frequency noise spectrum when the prediction verification is succeeded.

Preferably, the setting a single mode output light field of a laser includes:
setting the single mode output light field of the laser as a light field that fluctuates with an intensity and a phase and has monochromaticity meeting a set requirement according to a semi-classical theory of the laser:

$$E ( t ) = [ {E}_{0} + a ( t ) ] exp [ i ( 2 π {v}_{0} t + φ ( t ) ) ] , \qquad ( 1 )$$

where E₀ represents a constant amplitude of the light field, a(t) and φ(t) respectively represent random fluctuations of an amplitude and a phase of the light field, ν₀ represents a central frequency, and t represents time.

Preferably, the method further includes:
performing Fourier transform on an autocorrelation function of the light field to obtain the laser power spectrum:

$${S}_{E} ( f ) = {\int }_{- ∞}^{+ ∞} {R}_{E} ( τ ) exp ( - i 2 π f τ ) d τ , \qquad ( 2 )$$

where S_{E}(f) represents the laser power spectrum, τ represents a random fluctuation time interval of the phase, and R_{E}(τ) represents the autocorrelation function of the light field;

$${R}_{E} ( τ ) = < E ( t ) {E}^{*} ( t - τ ) \geq {E}_{0}^{2} exp ( i 2 π {v}_{0} τ ) < exp [ i Δφ ( t , τ ) ] > , \qquad ( 3 )$$

where the inside of < > represents a population mean, and Δφ(t, τ) represents a random phase change at a time interval τ;
Δφ(t, τ) is considered as a stationary Gaussian random fluctuation process with a mean of 0, then:

$$exp [ i Δφ ( t , τ ) ] = exp [ - \frac{1}{2} < Δ {φ}^{2} ( τ ) > ] , \qquad ( 4 )$$

where

$$< {Δφ}^{2} ( τ ) > = {\int }_{- ∞}^{+ ∞} {S}_{Δφ} ( f ) df ; {S}_{Δφ} ( f )$$

represents a power spectral density function of a differential phase fluctuation;
a power spectral density function S_{F}(f) of an instantaneous frequency fluctuation and the power spectral density function S_{φ}(f) of an instantaneous phase fluctuation are introduced, and a relationship among S_{Δφ}(f), S_{F}(f) and S_{φ}(f) is determined according to phase-shift theorem in Fourier transform and Euler's formula:

$${S}_{F} ( f ) = {f}^{2} {S}_{φ} ( f ) = \frac{{f}^{2}}{4 {sin}^{2} ( π f τ )} {S}_{Δφ} ( f ) ; \qquad ( 5 )$$

$$< {Δφ}^{2} ( τ ) > = {\int }_{- ∞}^{+ ∞} \frac{4 {sin}^{2} ( π f τ )}{{f}^{2}} {S}_{F} ( f ) df \qquad ( 6 )$$

can be obtained;
formula (6) is substituted into formula (3) to obtain the autocorrelation function of the light field as follows:

$${R}_{E} ( τ ) = {E}_{0}^{2} exp ( i 2 π {v}_{0} τ ) {\int }_{- ∞}^{+ ∞} \frac{- 2 {sin}^{2} ( π f τ )}{{f}^{2}} {S}_{F} ( f ) df ; \qquad ( 7 )$$

formula (7) is substituted into formula (2), then the laser power spectrum S_{E}(f) is represented as:

$${S}_{E} ( f ) = {\int }_{- ∞}^{+ ∞} {E}_{0}^{2} exp ( i 2 π {v}_{0} τ ) exp ( - 2 {\int }_{0}^{+ ∞} {S}_{F} ( f ) {sin}^{2} ( π f τ ) / {f}^{2} df ) exp ( - i 2 π f τ ) d τ \# ; \qquad ( 8 )$$

the disturbance of the radio frequency white noise in electricity is converted to the phase disturbance of the light field to obtain the converted power spectral density;

$${S}_{F} = \frac{{π}^{2} {S}_{V}}{{V}_{π}^{2}} , \qquad ( 9 )$$

where S_{F} represents the converted power spectral density, and S_{V} represents the power spectral density before converting;
formula (8) and formula (9) are combined to obtain:

$${S}_{E} ( f ) = {\int }_{- ∞}^{+ ∞} {E}_{0}^{2} exp ( i 2 π {v}_{0} τ ) exp [ - {S}_{E} {f}_{c} ( 1 - sinc ( 2 {f}_{c} τ ) ) ] exp ( - i 2 π f τ ) d τ \# , \qquad ( 10 )$$

where f_{c} represents the maximum cutoff frequency of the radio frequency white noise generated by the radio frequency noise source;
for the off-axis integrated cavity system with a length of d and a cavity mirror reflectivity of R, the spectral absorption coefficient α inside the cavity is represented as:

$$α = \frac{1}{d} \vert ln \{ \frac{1}{2 {R}^{2}} [ \sqrt{4 {R}^{2} + \frac{{I}_{0}^{2}}{{I}^{2}} {( 1 - {R}^{2} )}^{2}} - \frac{{I}_{0}}{I} ( 1 - {R}^{2} ) ] \} \vert , \qquad ( 11 )$$

where I₀ is the initial light intensity, I represents the real-time light intensity, and when R→1, exp(αd)→0, then formula (11) is simplified as:

$$α \approx \frac{1}{d} ( \frac{{I}_{0}}{I} - 1 ) ( 1 - R ) = \frac{1}{d} ( 1 - R ) ln ( \frac{I}{{I}_{0}} ) ; \qquad ( 12 )$$

and
the forward fitting model containing the spectral absorption coefficient of the radio frequency white noise may be obtained by combining formula (10) and formula (12):

$$α = \frac{1}{d} {\int }_{- ∞}^{+ ∞} ln ( \frac{I}{{I}_{0}} ) exp ( i 2 π {v}_{0} τ ) exp [ - {S}_{E} {f}_{c} ( 1 - sinc ( 2 {f}_{c} τ ) ) ] exp ( - i ωτ ) d τ \# . \qquad ( 13 )$$

According to a second aspect of the embodiments of this application, a device for fitting a spectrum in an off-axis integrated cavity disturbed by radio frequency noise is provided, including:
a processor and a memory.

The processor is connected to the memory through a communication bus.

The processor is configured to call and execute a program stored in the memory.

The memory is configured to store the program. The program is at least configured to perform the method for fitting a spectrum in an off-axis integrated cavity disturbed by radio frequency noise according to any one of items described above.

The technical solution provided in the embodiments of this application may include the following beneficial benefits:

The method for fitting a spectrum in an off-axis integrated cavity disturbed by radio frequency noise in this application includes: setting a single mode output light field of a laser; obtaining a maximum cutoff frequency and a power spectral density of radio frequency white noise generated by a radio frequency noise source, and converting a disturbance of the radio frequency white noise in electricity to a phase disturbance of the light field to obtain a converted power spectral density; determining a laser power spectrum according to the set light field, and the maximum cutoff frequency and the converted power spectral density of the radio frequency white noise; obtaining a length and a cavity mirror reflectivity of an off-axis integrated cavity system, and an initial light intensity and a real-time light intensity when the off-axis integrated cavity system runs; and constructing a forward fitting model containing a spectral absorption coefficient of the radio frequency white noise when the cavity mirror reflectivity of the off-axis integrated cavity system approaches 1. The forward fitting model is represented as a functional relationship between the spectral absorption coefficient inside the cavity and the laser power spectrum, the length of the off-axis integrated cavity system, and the initial light intensity and the real-time light intensity when the off-axis integrated cavity system runs.

According to this technical solution, a functional correspondence between the single mode output light field of the laser and the radio frequency white noise is constructed to obtain the forward fitting model containing the spectral absorption coefficient of the radio frequency white noise to achieve accurate fitting of a broadened absorption spectral line, reduce a system fitting error, and improve measurement accuracy.

It is to be understood that the above general descriptions and the following detailed descriptions are only exemplary and explanatory, and cannot limit this application.

### BRIEF DESCRIPTION OF THE DRAWINGS

Accompanying drawings herein are incorporated in the specification as a part of this specification, which show embodiments that are in accordance with this application, and are used together with the specification to explain a principle of this application.

FIG. 1 is a schematic flowchart of a method for fitting a spectrum in an off-axis integrated cavity disturbed by radio frequency noise provided in an embodiment of this application;

FIG. 2 is a schematic structural diagram of an off-axis integrated cavity provided in an embodiment of this application;

FIG. 3a is an absorption spectrogram of a gas under different white noise power injections provided in an embodiment of this application;

FIG. 3b is an absorption spectrogram of a gas obtained through simulation of a forward fitting model under different white noise power injections provided in an embodiment of this application;

FIG. 4 is a schematic diagram of a fitting result obtained through simulation of a forward fitting model provided in an embodiment of this application; and

FIG. 5 is a schematic structural diagram of a device for fitting a spectrum in an off-axis integrated cavity disturbed by radio frequency noise provided in an embodiment of this application.

Reference signs in the drawings: noise source—1; T-shaped bias module—2; laser drive module—3; laser—4; optical resonant cavity—5; front high reflection mirror—6a; rear high reflection mirror—6b; gas inlet—7a; gas outlet—7b; collimation module—8; detection module—9; processor—21; and memory—22.

### DETAILED DESCRIPTION OF THE EMBODIMENTS

Exemplary embodiments are described in detail herein, and examples of the embodiments are presented in accompanying drawings. When the following description involves the accompanying drawings, unless specified otherwise, same numbers in different accompanying drawings represent the same or similar elements. Implementations described in the following exemplary embodiments do not represent all implementations consistent with this application. On the contrary, they are only examples of apparatuses and methods that are described in the appended claims in detail and that are consistent with some aspects of this application.

### Embodiment 1

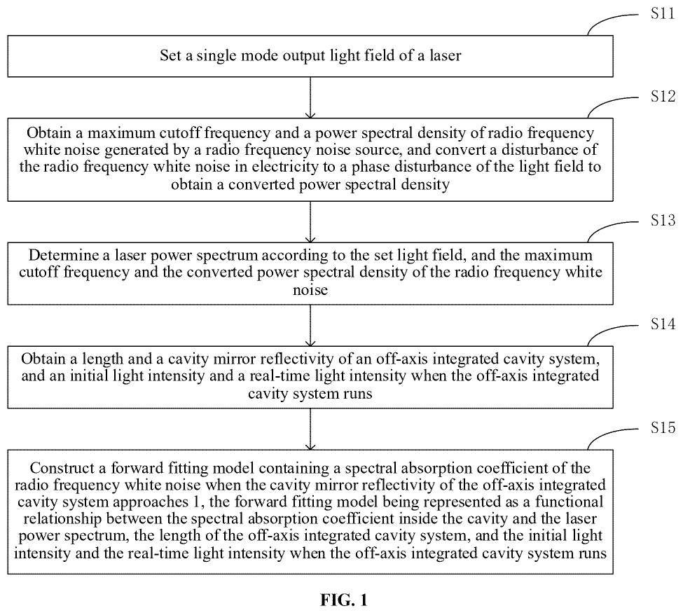

FIG. 1 is a schematic flowchart of a method for fitting a spectrum in an off-axis integrated cavity disturbed by radio frequency noise provided in an embodiment of this application. Referring to FIG. 1, a method for fitting a spectrum in an off-axis integrated cavity disturbed by radio frequency noise includes the following steps:

S11: A single mode output light field of a laser is set.

S12: A maximum cutoff frequency and a power spectral density of radio frequency white noise generated by a radio frequency noise source are obtained, and a disturbance of the radio frequency white noise in electricity is converted to a phase disturbance of the light field to obtain a converted power spectral density.

S13: A laser power spectrum is determined according to the set light field, and the maximum cutoff frequency and the converted power spectral density of the radio frequency white noise.

S14: A length and a cavity mirror reflectivity of an off-axis integrated cavity system, and an initial light intensity and a real-time light intensity when the off-axis integrated cavity system runs are obtained.

S15: A forward fitting model containing a spectral absorption coefficient of the radio frequency white noise is constructed when the cavity mirror reflectivity of the off-axis integrated cavity system approaches 1. The forward fitting model is represented as a functional relationship between the spectral absorption coefficient inside the cavity and the laser power spectrum, the length of the off-axis integrated cavity system, and the initial light intensity and the real-time light intensity when the off-axis integrated cavity system runs.

It is to be noted that, during implementation of this technical solution, the single mode output light field of the laser is first set as a light field that fluctuates with an intensity and a phase and has monochromaticity meeting a set requirement according to a semi-classical theory of the laser:

$$E ( t ) = [ {E}_{0} + a ( t ) ] exp [ i ( 2 π {v}_{0} t + φ ( t ) ) ] , \qquad ( 1 )$$

where E₀ represents a constant amplitude of the light field, a(t) and φ(t) respectively represent random fluctuations of an amplitude and a phase of the light field, ν₀ represents a central frequency, and t represents time.

In specific practice, the light field meets a requirement of not having strict monochromaticity.

Under normal conditions, an impact of an amplitude fluctuation on the spectrum can be negligible. Only φ(t) is considered here, and the laser power spectrum is obtained by performing Fourier transform on an autocorrelation function of the light field according to Wiener-Khintchine theorem.

Fourier transform is performed on the autocorrelation function of the light field to obtain the laser power spectrum:

$${S}_{E} ( f ) = {\int }_{- ∞}^{+ ∞} {R}_{E} ( τ ) exp ( - i 2 π f τ ) d τ , \qquad ( 2 )$$

where S_{E}(f) represents the laser power spectrum, τ represents a random fluctuation time interval of the phase, and R_{E}(τ) represents the autocorrelation function of the light field;

$${R}_{E} ( τ ) = < E ( t ) {E}^{*} ( t - τ ) \geq {E}_{0}^{2} exp ( i2 π {v}_{0} τ ) < exp [ i Δφ ( t , τ ) ] > ; \qquad ( 3 )$$

where the inside of < > represents a population mean, and Δφ(t, τ) represents a random phase change at a time interval τ;
Δφ(t, τ) is considered as a stationary Gaussian random fluctuation process with a mean of 0, then:

$$exp [ i Δφ ( t , τ ) ] = exp [ - \frac{1}{2} < {Δφ}^{2} ( τ ) > ] , \qquad ( 4 )$$

where

$$< {Δφ}^{2} ( τ ) > = {\int }_{- ∞}^{+ ∞} {S}_{Δφ} ( f ) df ; {S}_{Δφ} ( f )$$

represents a power spectral density function of a differential phase fluctuation;
a power spectral density function S_{F}(f) of an instantaneous frequency fluctuation and the power spectral density function S_{φ}(f) of an instantaneous phase fluctuation are introduced, and a relationship among S_{Δφ}(f), S_{F}(f) and S_{φ}(f) is determined according to phase-shift theorem in Fourier transform and Euler's formula:

$${S}_{F} ( f ) = {f}^{2} {S}_{φ} ( f ) = \frac{{f}^{2}}{4 {sin}^{2} ( π f τ )} {S}_{Δφ} ( f ) ; \qquad ( 5 )$$

$$< {Δφ}^{2} ( τ ) > = {\int }_{- ∞}^{+ ∞} \frac{4 {sin}^{2} ( π f τ )}{{f}^{2}} {S}_{F} ( f ) df \qquad ( 6 )$$

may be obtained;
formula (6) is substituted into formula (3) to obtain the autocorrelation function of the light field as follows:

$${R}_{E} ( τ ) = {E}_{0}^{2} exp ( i 2 π {v}_{0} τ ) {\int }_{- ∞}^{+ ∞} \frac{- 2 {sin}^{2} ( π f τ )}{{f}^{2}} {S}_{F} ( f ) df ; \qquad ( 7 )$$

formula (7) is substituted into formula (2), then the laser power spectrum S_{E}(f) is represented as:

$${S}_{E} ( f ) = {\int }_{- ∞}^{+ ∞} {E}_{0}^{2} exp ( i 2 π {v}_{0} τ ) exp ( - 2 {\int }_{0}^{+ ∞} {S}_{F} ( f ) {sin}^{2} ( π f τ ) / {f}^{2} df ) exp ( - i 2 π f τ ) d τ \# ; \qquad ( 8 )$$

the disturbance of the radio frequency white noise in electricity is converted to the phase disturbance of the light field to obtain the converted power spectral density;

$${S}_{F} = \frac{{π}^{2} {S}_{V}}{{V}_{π}^{2}} , \qquad ( 9 )$$

where S_{F} represents the converted power spectral density, and S_{V} represents the power spectral density before converting;
formula (8) and formula (9) are combined to obtain:

$${S}_{E} ( f ) = {\int }_{- ∞}^{+ ∞} {E}_{0}^{2} exp ( i 2 π {v}_{0} τ ) exp [ - {S}_{E} {f}_{c} ( 1 - sinc ( 2 {f}_{c} τ ) ) ] exp ( - i 2 π f τ ) d τ \# , \qquad ( 10 )$$

where f_{c} represents the maximum cutoff frequency of the radio frequency white noise generated by the radio frequency noise source;
for the off-axis integrated cavity system with a length of d and a cavity mirror reflectivity of R, the spectral absorption coefficient α inside the cavity is represented as:

$$α = \frac{1}{d} \vert ln \{ \frac{1}{2 {R}^{2}} [ \sqrt{4 {R}^{2} + \frac{{I}_{0}^{2}}{{I}^{2}} {( 1 - {R}^{2} )}^{2}} - \frac{{I}_{0}}{I} ( 1 - {R}^{2} ) ] \} \vert , \qquad ( 11 )$$

where I₀ is the initial light intensity, I represents the real-time light intensity, and when R→1, exp(αd)→0, then formula (11) is simplified as:

$$α \approx \frac{1}{d} ( \frac{{I}_{0}}{1} - 1 ) ( 1 - R ) = \frac{1}{d} ( 1 - R ) ln ( \frac{I}{{I}_{0}} ) ; \qquad ( 12 )$$

and
the forward fitting model containing the spectral absorption coefficient of the radio frequency white noise may be obtained by combining formula (10) and formula (12):

$$α = \frac{1}{d} {\int }_{- ∞}^{+ ∞} ln ( \frac{I}{{I}_{0}} ) exp ( i 2 π {ν}_{0} τ ) exp [ - {S}_{E} {f}_{c} ( 1 - sin c ( 2 {f}_{c} τ ) ) ] exp ( - i ωτ ) d τ . \qquad \# ( 13 )$$

It is to be noted that, method further includes the following steps:

The spectral absorption coefficient inside the cavity when an off-axis integrated cavity spectrum runs is obtained according the forward fitting model, and a fitting result is generated.

Fitting verification is performed on the fitting result according to fitting verification data.

When the fitting verification fails, the forward fitting model is modified until the fitting verification is succeeded.

A prediction result is generated according the forward fitting model when the verification fitting is succeeded.

Prediction verification is performed on the prediction result according to prediction verification data.

When the prediction verification fails, the forward fitting model is modified until the prediction verification is succeeded.

The forward fitting model is applied to fitting the spectrum in the off-axis integrated cavity disturbed by the radio frequency noise when the prediction verification is succeeded.

The forward fitting model containing the spectral absorption coefficient of the radio frequency white noise in this technical solution is verified through specific experiments.

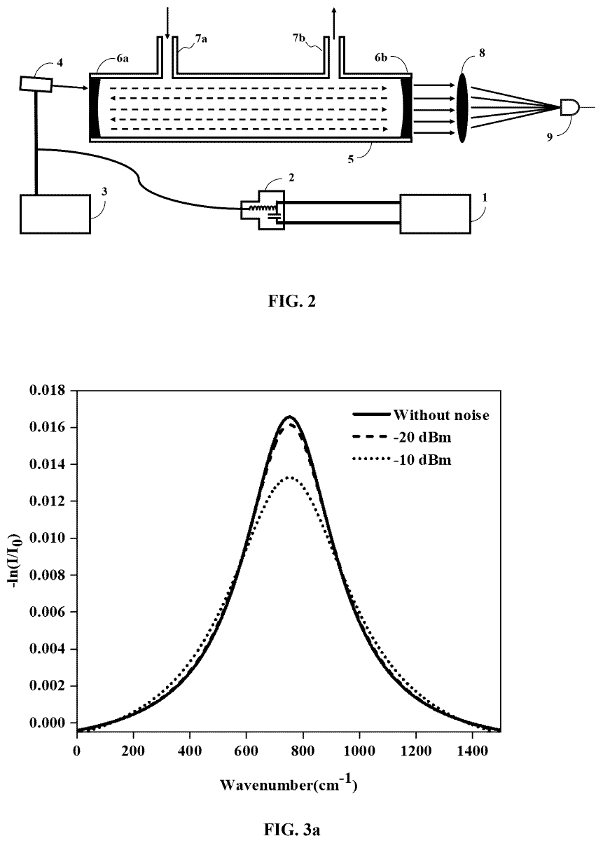

An off-axis integrated cavity for trace gas detection based on radio frequency white noise as shown in FIG. 2 includes:
a noise source 1, a T-shaped bias module 2, a laser drive module 3, a laser 4, an optical resonant cavity 5, a front high reflection mirror 6a, a rear high reflection mirror 6b, a gas inlet 7a, a gas outlet 7b, a collimation module 8, and a detection module 9. The laser drive module 3 modulates the laser 4 by using a periodic waveform and drives the laser 4 to emit laser. The laser emits into the optical resonant cavity 5 off axis after being emitted from the laser 4. The front high reflection mirror 6a and the rear high reflection mirror 6b are embedded into two ends of the optical resonant cavity 5. The laser is transmitted out through the rear high reflection mirror 6b after being reflected for a plurality of times in the optical resonant cavity 5, is collimated and focused by the collimation module 8, and is received and measured by the detection module 9.

During implementing, the noise source 1 generates white Gaussian noise with different power of −20 dBm and −10 dBm respectively, and the T-shaped bias module 2 injects the noise into the laser 4. After an input current of the laser 4 is disturbed through the noise source 1, a linewidth and a line type of a laser output power spectrum change, and then the linewidth and the line type of an absorption spectrum of a gas significantly change.

In specific practice, the front high reflection mirror 6a and the rear high reflection mirror 6b are quartz plano-concave spherical mirrors or plano-concave cylindrical mirrors. A concave surface is coated with a reflective coating with a reflectivity of greater than 99.9%, and a flat surface is coated with an anti-reflecting coating.

The gas inlet 7a and the gas outlet 7b can uninterruptedly enable the gas to be detected to flow in and out of the optical resonant cavity 5.

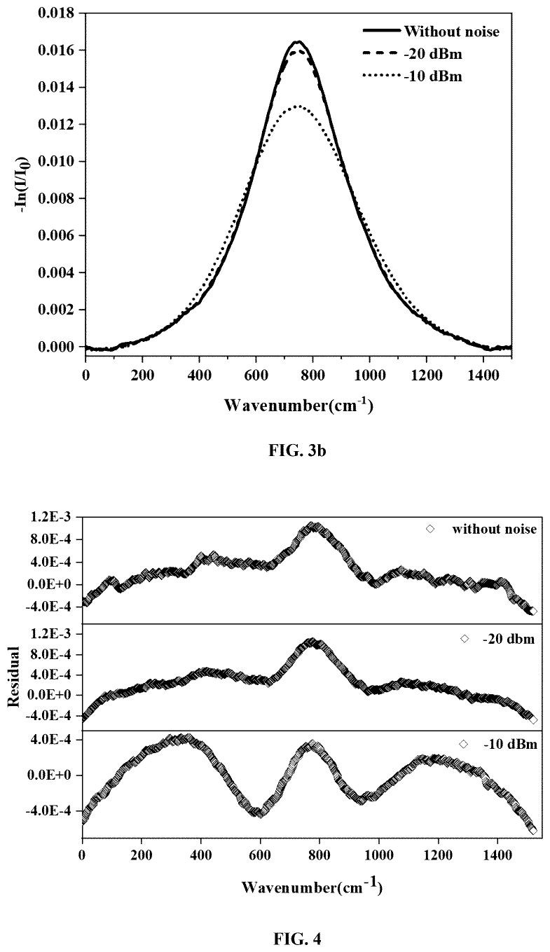

Taking CO₂ gas as an example, FIG. 3a and FIG. 3b are an absorption spectrogram of a gas under different white noise power injections and an absorption spectrogram under the same condition obtained by using simulation of the forward fitting model of this technical solution.

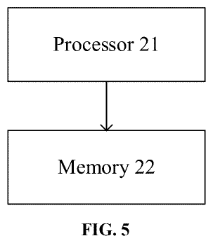

Specifically, an absorption spectrum after white noise without radio frequency at the power of −20 dBm and −10 dBm obtained by using the forward fitting model of this technical solution is simulated and fitted, and a residual for raw data is calculated. By analyzing in combination with actual data and the fitting result, it can be known that, as shown in FIG. 4, residuals of three curves of white noise at different power are respectively within +/−1.1E-3, +/−1.05E-3, and +/−4E-4, which indicates that observation values in a dataset are relatively consistent. It is proved that prediction accuracy of the model is relatively high; root mean square errors are respectively 2.7E-5, 2.6E-5, and 1.6E-5, which indicates that the model has a good fitting effect, and can accurately reflect a relationship in the dataset. In conclusion, a simulation effect of the forward fitting model of this technical solution is basically consistent with an actual experimental result, which proves that the model performs well in terms of fitting accuracy and application practicability.

According to the technical solution, a physical model of radio frequency noise on optical cavity mode noise is derived based on principles, broadened absorption spectra disturbed by radio frequency noise at different power are fitted accurately, a blank that a conventional spectral line function cannot fit at the present stage is filled, a fitting error of a system is greatly reduced, and measurement accuracy of the system is improved.

### Embodiment 2

FIG. 5 is a schematic structural diagram of a device for fitting a spectrum in an off-axis integrated cavity disturbed by radio frequency noise provided in an embodiment of this application. Referring to FIG. 5, a device for fitting a spectrum in an off-axis integrated cavity disturbed by radio frequency noise includes:
a processor 21 and a memory 22.

The processor 21 is connected to the memory 22 through a communication bus.

The processor 21 is configured to call and execute a program stored in the memory 22.

The memory 22 is configured to store the program. The program is at least configured to perform the method for fitting a spectrum in an off-axis integrated cavity disturbed by radio frequency noise in the above embodiments.

It may be understood that the same or similar parts in various embodiments described above may be referenced to each other. In some embodiments, the content not detailed in some embodiments can be referenced to the same or similar content in other embodiments.

It is to be noted that, in the description of this application, terms “first”, “second”, and the like are merely used for description, and cannot be understood as indicating or implying relative importance. In addition, in the description of this application, unless otherwise specified, “multiple” means at least two.

Any process or method description in the flowchart or described herein in another manner may be understood as representing a module, segment or part including code of one or more executable instructions configured to realize specific logic functions or steps of the process, and moreover, a scope of a preferred implementation of this application includes other implementations. Involved functions may not be performed in a sequence shown or discussed herein, but may be performed basically simultaneously or in a reverse sequence, which is to be understood by those skilled in the art of the embodiments of this application.

It is to be understood that various parts of this application may be implemented by hardware, software, firmware or a combination thereof. In the implementations described above, multiple steps or methods may be implemented by software or firmware stored in a memory and executed by a proper instruction execution system. For example, in case of implementing with the hardware, like another implementation, any one or a combination of the following technologies well-known in the art may be adopted for implementing: a discrete logic circuit with a logic gate circuit configured to realize a logic function for a data signal, an application-specific integrated circuit with a proper combined logic gate circuit, a Programmable Gate Array (PGA), a Field Programmable Gate Array (FPGA), and the like.

Those of ordinary skill in the art may understand that all or part of the steps in the method of the embodiments described above may be completed through related hardware instructed by a program. The program may be stored in a computer-readable storage medium, and when the program is executed, one or combination of the steps of the method embodiment is included.

In addition, various functional units in each embodiment of this application may be integrated into one processing module, or various units may exist physically independently, or two or more than two units may be integrated into one module. The integrated module described above may be implemented in a form of hardware, or may be implemented in a form of a software functional module. When implemented in form of software functional module and sold or used as an independent product, the integrated module may be stored in a computer-readable storage medium.

The storage medium mentioned above may be a Read-Only Memory (ROM), a magnetic disk, an optical disk, or the like.

In the descriptions of this specification, the descriptions made with reference to terms such as “an embodiment”, “some embodiments”, “example”, “specific example”, or “some examples” refer to that specific features, structures, materials or characteristics described in combination with the embodiments or the examples are included in at least one embodiment or example of this application. In this specification, schematic expressions of the terms described above do not necessarily refer to the same embodiment or example. Moreover, the described specific features, structures, materials, or characteristics may be combined in a suitable manner in any one or more embodiments or examples.

Although the embodiments of this application have been shown or described above, it may be understood that the above embodiments are exemplary and cannot be understood as a limitation to this application. Those of ordinary skill in the art may make variations, modifications, replacements, transformations to the embodiments described above within the scope of this application.

What is claimed is:

1. A method for fitting a spectrum in an off-axis integrated cavity disturbed by radio frequency noise, comprising:
setting a single mode output light field of a laser;
obtaining a maximum cutoff frequency and a power spectral density of radio frequency white noise generated by a radio frequency noise source, and converting a disturbance of the radio frequency white noise in electricity to a phase disturbance of the light field to obtain a converted power spectral density;
determining a laser power spectrum according to the set light field, and the maximum cutoff frequency and the converted power spectral density of the radio frequency white noise;
obtaining a length and a cavity mirror reflectivity of an off-axis integrated cavity system, and an initial light intensity and a real-time light intensity when the off-axis integrated cavity system runs; and
constructing a forward fitting model containing a spectral absorption coefficient of the radio frequency white noise when the cavity mirror reflectivity of the off-axis integrated cavity system approaches 1, the forward fitting model being represented as a functional relationship of a spectral absorption coefficient inside the cavity and the laser power spectrum, the length of the off-axis integrated cavity system, and the initial light intensity and the real-time light intensity when the off-axis integrated cavity system runs.

2. The method according to claim 1, further comprising:
obtaining the spectral absorption coefficient inside the cavity when the off-axis integrated cavity spectrum runs according to the forward fitting model, and generating a fitting result;
performing fitting verification on the fitting result according to fitting verification data; and
when fitting verification fails, modifying the forward fitting model until fitting verification is succeeded.

3. The method according to claim 2, further comprising:
generating a prediction result according to the forward fitting model when the fitting verification is succeeded; and
performing prediction verification on the prediction result according to prediction verification data; and
when the prediction verification fails, modifying the forward fitting model until the prediction verification is succeeded.

4. The method according to claim 3, further comprising:
applying the forward fitting model to fitting the spectrum in the off-axis integrated cavity disturbed by the radio frequency noise when the prediction verification is succeeded.

5. The method according to claim 1, wherein the setting a single mode output light field of a laser comprises:
setting the single mode output light field of the laser as a light field that fluctuates with an intensity and a phase and has monochromaticity meeting a set requirement according to a semi-classical theory of the laser:
$$E ( t ) = [ {E}_{0} + a ( t ) ] exp [ i ( 2 {πν}_{0} t + φ ( t ) ) ] , \qquad ( 1 )$$
wherein E₀ represents a constant amplitude of the light field, a(t) and φ(t) respectively represent random fluctuations of an amplitude and a phase of the light field, ν₀ represents a central frequency, and t represents time.

6. The method according to claim 1, further comprising:
performing Fourier transform on an autocorrelation function of the light field to obtain the laser power spectrum:
$${S}_{E} ( f ) = {\int }_{- ∞}^{+ ∞} {R}_{E} ( τ ) exp ( - i 2 π f τ ) d τ , \qquad ( 2 )$$
wherein S_{E}(f) represents the laser power spectrum, τ represents a random fluctuation time interval of the phase, and R_{E}(τ) represents the autocorrelation function of the light field;
$${R}_{E} ( τ ) = < E ( t ) {E}^{*} ( t - τ ) \geq {E}_{0}^{2} exp ( i 2 {πν}_{0} τ ) < exp [ i Δφ ( t , τ ) ] > , \qquad ( 3 )$$
wherein the inside of < > represents a population mean, and Δφ(t, τ) represents a random phase change at a time interval τ;
considering Δφ(t, τ) as a stationary Gaussian random fluctuation process with a mean of 0, then:
$$exp [ i Δφ ( t , τ ) ] = exp [ - \frac{1}{2} < {Δφ}^{2} ( τ ) > ] , \qquad ( 4 )$$
wherein
$$< {Δφ}^{2} ( τ ) > = {\int }_{- ∞}^{+ ∞} {S}_{Δφ} ( f ) df ; {S}_{Δφ} ( f )$$
represents a power spectral density function of a differential phase fluctuation;
a power spectral density function S_{F}(f) of an instantaneous frequency fluctuation and a power spectral density function S_{φ}(f) of an instantaneous phase fluctuation are introduced, and a relationship among S_{Δφ}(f), S_{F}(f) and S_{φ}(f) is determined according to phase-shift theorem in Fourier transform and Euler's formula:
$${S}_{F} ( f ) = {f}^{2} {S}_{φ} ( f ) = \frac{{f}^{2}}{4 {sin}^{2} ( π f τ )} {S}_{Δφ} ( f ) ; \qquad ( 5 )$$
$$< {Δφ}^{2} ( τ ) > = {\int }_{- ∞}^{+ ∞} \frac{4 {sin}^{2} ( π f τ )}{{f}^{2}} {S}_{F} ( f ) d f \qquad ( 6 )$$
may be obtained;
formula (6) is substituted into formula (3) to obtain the autocorrelation function of the light field as follows:
$${R}_{E} ( τ ) = {E}_{0}^{2} exp ( i 2 {πν}_{0} τ ) {\int }_{- ∞}^{+ ∞} \frac{- 2 {sin}^{2} ( π f τ )}{{f}^{2}} {S}_{F} ( f ) df ; \qquad ( 7 )$$
formula (7) is substituted into formula (2), then the laser power spectrum S_{E}(f) is represented as:
$${S}_{E} ( f ) = {\int }_{- ∞}^{+ ∞} {E}_{0}^{2} exp ( i 2 {πν}_{0} τ ) exp ( - 2 {\int }_{0}^{+ ∞} {S}_{F} ( f ) {sin}^{2} ( π f τ ) / {f}^{2} df ) exp ( - i 2 π f τ ) d τ ; \qquad \# ( 8 )$$
the disturbance of the radio frequency white noise in electricity is converted to the phase disturbance of the light field to obtain the converted power spectral density;
$${S}_{F} = \frac{{π}^{2} {s}_{V}}{{V}_{π}^{2}} , \qquad ( 9 )$$
wherein S_{F} represents the converted power spectral density, and S_{V} represents power spectral density before converting;
formula (8) and formula (9) are combined to obtain:
$${S}_{E} ( f ) = {\int }_{- ∞}^{+ ∞} {E}_{0}^{2} exp ( i 2 {πν}_{0} τ ) exp [ - {S}_{E} {f}_{c} ( 1 - sin c ( 2 {f}_{c} τ ) ) ] exp ( - i 2 π f τ ) d τ , \qquad \# ( 10 )$$
wherein f_{c} represents the maximum cutoff frequency of the radio frequency white noise generated by the radio frequency noise source;
for the off-axis integrated cavity system with a length of d and a cavity mirror reflectivity of R, the spectral absorption coefficient α inside the cavity is represented as:
$$α = \frac{1}{d} \vert ln \{ \frac{1}{2 {R}^{2}} [ \sqrt{4 {R}^{2} + \frac{{I}_{0}^{2}}{{I}^{2}} {( 1 - {R}^{2} )}^{2}} - \frac{{I}_{0}}{I} ( 1 - {R}^{2} ) ] \} \vert , \qquad ( 11 )$$
wherein I₀ is the initial light intensity, I represents the real-time light intensity, and when R→1, exp(αd)→0, then formula (11) is simplified as:
$$α \approx \frac{1}{d} ( \frac{{I}_{0}}{I} - 1 ) ( 1 - R ) = \frac{1}{d} ( 1 - R ) ln ( \frac{I}{{I}_{0}} ) ; \qquad ( 12 )$$
and
the forward fitting model containing the spectral absorption coefficient of the radio frequency white noise is capable of being be obtained by combining formula (10) and formula (12):
$$α = \frac{1}{d} {\int }_{- ∞}^{+ ∞} ln ( \frac{I}{{I}_{0}} ) exp ( i 2 π {ν}_{0} τ ) exp [ - {S}_{E} {f}_{c} ( 1 - sin c ( 2 {f}_{c} τ ) ) ] exp ( - i ωτ ) d τ . \qquad \# ( 13 )$$

7. A device for fitting a spectrum in an off-axis integrated cavity disturbed by radio frequency noise, comprising:
a processor and a memory,
the processor being connected to the memory through a communication bus, wherein
the processor is configured to call and execute a program stored in the memory; and
the memory is configured to store the program; and the program is at least configured to perform a method for fitting a spectrum in an off-axis integrated cavity disturbed by radio frequency noise according to claim 1.
